(19) United States
(12) Patent Application Publication
(10) Pub. No.: US 2010/0314641 A1
(43) Pub. Date: Dec. 16, 2010

(54) Lighting Device

(76) Inventor: Hans-Joachim Schmidt, Ingolstadt (DE)

Correspondence Address: SLATER & MATSIL, L.L.P., 17950 PRESTON RD, SUITE 1000, DALLAS, TX, 75252-5793, US

(21) Appl. No.: 12/446,181

(22) PCT Filed: Oct. 25, 2006
(86) PCT No.: PCT/DE2006/001887

§ 371 Date: May 29, 2009

(51) Int. Cl. H01L 33/60; H01L 33/64

(52) U.S. Cl. 257/98; 257/E33.072; 257/E33.075

(57) ABSTRACT

A lighting device can include at least one optoelectronic semiconductor chip, which emits electromagnetic radiation and generates heat in operation, and a reflector. The reflector is suitable for deflecting the electromagnetic radiation and dissipating the heat generated by the optoelectronic semiconductor chip by means of a reflecting surface.

The present invention relates to alighting device.

### BACKGROUND

Document WO 2005/085706 A1, U.S. equivalent 2007/0189017, describes a lamp with a reflector and a heat sink.

### SUMMARY

Embodiments of the present invention disclose a lighting device with a radiation source, wherein the lighting device is suitable for deflecting the electrical radiation emitted by the radiation source and dissipating the heat generated by the radiation source.

A lighting device according to one particular embodiment includes at least one optoelectronic semiconductor chip, which in operation emits electromagnetic radiation and generates heat. A reflector, deflects electromagnetic radiation by means of a reflecting surface. The reflector also dissipates the heat generated by the optoelectronic semiconductor chip.

Advantageously, this can make it possible to provide a lighting device in which the reflector also acts as a heat sink for the optoelectronic semiconductor chip. Thereby, the reflector can deflect the electromagnetic radiation generated by the optoelectronic semiconductor chip, in particular into a room area that is to be lit.

In one embodiment, “electromagnetic radiation” refers to light in an ultraviolet to infrared wavelength range. Particularly preferably, the electromagnetic radiation comprises a visible wavelength range, alternatively or additionally also comprises an infrared wavelength range, in particular a wavelength range in the near infrared. The electromagnetic radiation preferably comprises in particular a wavelength range which can create a single color or mixed color light effect to an observer. For this purpose, the optoelectronic semiconductor chip can emit electromagnetic radiation with one wavelength, a range of wavelengths or a plurality of wavelengths. Particularly preferably, the optoelectronic semiconductor chip can create a white light impression to an observer.

Thereby, the optoelectronic semiconductor chip can comprise at least one semiconductor layer sequence which is suitable for generating electromagnetic radiation in operation. In addition to this, the optoelectronic semiconductor chip can comprise additional elements such as, for example, a housing, an encapsulation, a fluorescence conversion layer or a fluorescence conversion element, a light deflecting optical element, such as a lens, or electrical contacts. The materials and structure of a radiation generating semiconductor layer sequence and the additional elements are known to a person skilled in the art and are therefore not discussed further at this point. In particular, the optoelectronic semiconductor chip can have a mounting surface with which the optoelectronic semiconductor chip can be mounted and/or assembled, for example onto the reflector. In this case the side of the optoelectronic semiconductor chip opposite to the mounting surface can form an upper side of the semiconductor chip.

In one preferred embodiment, the heat generated by the optoelectronic semiconductor and dissipated by the reflector is emitted to the surroundings by the reflector via a surface. In particular, the surface can comprise the reflecting surface, for example. This allows the heat, for example, to be emitted into the room area to be lit, into which the electromagnetic radiation is also deflected by the reflecting surface. Alternatively or additionally, the heat can be emitted to the environment via a surface of the reflector other than the reflecting surface, for example a surface of the reflector opposite to the reflecting surface. This allows heat to be emitted into a different spatial area of the environment than the spatial area to be lit, into which the electromagnetic radiation is deflected by the reflecting surface. In this case it can be advantageous if the reflector has large-area surfaces, which can facilitate efficient dissipation of the heat by the reflector and therefore also from the optoelectronic semiconductor chip to the environment.

In a particularly preferred embodiment, the heat generated by the optoelectronic semiconductor chip is emitted to the environment exclusively by the reflector. In this case, “exclusively by the reflector” can mean in particular that the total heat generated by the optoelectronic semiconductor chip which is not directly radiated by it to the environment via a surface, for example the upper side of the optoelectronic semiconductor chip, can be emitted to the environment via the reflector.

This makes it possible in particular for the lighting device not to have an additional heat sink, but rather the reflector also has the function of the heat sink. A lighting device of this kind can therefore be advantageously produced using a minimum amount of material and components. With regard to the economic efficiency of the lighting device, this also advantageously enables material, assembly and transport costs to be minimized. It can furthermore be possible, owing to the absence of a heat sink, that a lighting device can be produced which has smaller external dimensions and lower weight than lamps known in the prior art.

In particular, it can be advantageous if the reflector has a receiving region in which the optoelectronic semiconductor chip is mounted. The receiving region can comprise, for example, a part of the reflecting surface, or can adjoin the reflecting surface. Thereby, the receiving region can comprise, for example, a flat surface or a recess in the reflecting surface, or a flat surface or a recess which adjoins the reflecting surface.

In particular, a reflector of this kind with a receiving region can facilitate a small spacing between the optoelectronic semiconductor chip and the reflector, which can facilitate a compact lighting device.

At least one part of the flat surface or recess of the receiving region can be embodied as a contact surface. In particular, the optoelectronic semiconductor chip can be thermally coupled to the receiving region of the reflector and therefore to the reflector. For this purpose the optoelectronic semiconductor chip can have, for example, a mounting surface, which is in contact with the holding region of the reflector or, in particular, with the contact surface in the holding region. This can make it possible for heat generated by the optoelectronic semiconductor chip in operation to be dissipated to the reflector via its mounting surface. In particular, it can be advantageous if the contact surface of the receiving region is matched to the mounting surface of the optoelectronic semiconductor chip in such a way that a positive fitting arrangement and/or mounting of the optoelectronic semiconductor chip on the contact surface in the receiving region is possible. By means of a positive fitting arrangement and/or mounting a good thermal contact can be guaranteed between the optoelectronic semiconductor chip and the reflector.

In a further embodiment the lighting device comprises a spacing element that is arranged between the receiving region and the optoelectronic semiconductor chip. In particular, the spacing element can be arranged between the mounting surface of the optoelectronic semiconductor chip and the receiving region of the reflector, in particular the contact surface of the reflector. For example, the spacing element can be a spacer washer, which is suitable for thermally coupling the optoelectronic semiconductor chip, and in this case in particular, for example, the base surface of the optoelectronic semiconductor chip, to the receiving region of the reflector. Particularly preferably, the spacing element has a high thermal conductivity for this purpose. Due to the spacing element it can, for example, be possible to vary and optimize the position and arrangement of the optoelectronic semiconductor chip in the reflector. For example, the spacing element can comprise a thermally conducting material, for example a metal, a plastic, a ceramic or a combination of these. The spacing element can, for example, have a thickness of about a half up to several millimeters. In particular, the spacing element can be formed in such a way that it can be arranged in a positive fitting manner on the receiving region, in particular the contact surface in the receiving region, and on the mounting surface of the optoelectronic semiconductor chip, in order to facilitate a good thermal contact.

In a further embodiment, the lighting device comprises multiple spacing elements, which can each have equal or different thicknesses.

In a further embodiment the lighting device additionally comprises a carrier body. In this case it can be possible for the reflector to be mounted on the carrier body. It can furthermore be possible that the optoelectronic semiconductor chip and the reflector are both jointly mounted on the carrier body. For this purpose, the reflector can, for example, have openings in the receiving region, so that the optoelectronic semiconductor chip can be mounted on the carrier body through the openings in such a way that, when the optoelectronic semiconductor chip is mounted on the carrier body the reflector is also mounted on the carrier body, and therefore the optoelectronic semiconductor chip and the reflector are simultaneously mounted on the carrier body. Such a mounting capability can be facilitated, for example, by means of pin-shaped connecting elements, for example by means of a screw or plug connection.

In particular, a spacing element can also have suitable openings, such that the optoelectronic semiconductor chip can also be mounted on the carrier body by means of the openings of the spacing element.

In a further embodiment the reflector has at least one opening for passing through a power supply for the optoelectronic semiconductor chip. In particular, such an opening can be arranged to the side in the receiving region or in the reflecting surface. This opening can, for example, facilitate the passage of contact pins or electrical supply leads through to the semiconductor chip. Alternatively or additionally, the opening can be adapted as a leadthrough for an electrical contact of the optoelectronic semiconductor chip. Furthermore, the reflector can also have multiple openings, so that, for example, multiple contact pins, electrical supply leads or electrical contacts of the optoelectronic semiconductor chip can be guided through the reflector.

In another embodiment, the optoelectronic semiconductor chip is mounted on the reflector by means of a plug-in, screw, or clamp connection. This can advantageously allow the optoelectronic semiconductor chip to be removed from or to be mounted on the reflector, for example without damage to other parts, in particular the reflector. A plug-in, screw or clamp connection can thus guarantee a mechanical mounting capability. Such a connection can also facilitate an electrical contact. Alternatively or additionally, the optoelectronic semiconductor chip can also be mounted on the reflector, or in the receiving region of the reflector, and in particular on the contact surface of the receiving region, by means of a materially bonded connection. Such a materially bonded connection can be facilitated, for example, by a soldered or glued joint.

In a preferred embodiment the optoelectronic semiconductor chip has a rotationally symmetrical side-emitting emission characteristic. This can mean in particular that the optoelectronic semiconductor chip has a rotationally symmetrical emission characteristic, wherein only a small, or even no, component of the electromagnetic radiation is emitted from the upper side of the optoelectronic semiconductor chip, in particular in a direction perpendicular or essentially perpendicular to the mounting surface and/or upper side of the optoelectronic semiconductor chip, whereas electromagnetic radiation is emitted in a lateral direction. A “lateral direction” here can in particular be a direction which has a directional component parallel to the mounting surface of the optoelectronic semiconductor chip. An emission characteristic of this kind can be facilitated, for example, by a suitable housing shape or a suitable optical element, which is arranged as part of the optoelectronic semiconductor chip downstream of the radiation emitting semiconductor layer sequence in its radiation path.

In particular, a majority of the electromagnetic radiation can be emitted into a solid angular region of emission disposed laterally in relation to the mounting surface, which is bounded by a first and a second emission angle relative to a line perpendicular to the upper side, or to the mounting surface respectively, of the optoelectronic semiconductor chip. A “majority” here can refer to the spatial region which contains the intensity maximum of the radiation and is bounded by a drop in the intensity to, for example, 15% of the maximum. This can advantageously eliminate the need for a cap or screen arranged above the top of the optoelectronic semiconductor chip for screening electromagnetic radiation emitted from the top of the optoelectronic semiconductor chip, since the component of the electromagnetic radiation emitted from the top in a direction perpendicular to the mounting surface or the top is preferably less than or equal to 20%, more preferably less than or equal to 15% and particular preferably less than or equal to 5%.

Particularly preferably, the optoelectronic semiconductor chip can be arranged with respect to the reflecting surface in such a way that the majority of the electromagnetic radiation from the optoelectronic semiconductor chip is emitted onto the reflecting surface. This can mean in particular that the reflecting surface covers the solid angular emission region of the optoelectronic semiconductor chip. For this purpose, the reflecting surface can be bounded by a first and a second boundary line, which cover the first and the second emission angle of the solid angular emission region, so that only the part of the electromagnetic radiation which is emitted into the solid angular emission region is deflected by the reflecting surface into the room area to be lit.

In a preferred embodiment the reflector is in the form of a collimator, so that the electromagnetic radiation deflected by the reflecting surface into the room area to be lit can be emitted by the lighting device in the form of a beam and with minimal or no divergence. Here the reflecting surface can comprise a focal point and the optoelectronic semiconductor chip an emission focal point or light focal point, wherein the emission focal point is arranged at the focal point of the reflecting surface. The term “emission focal point” can mean here that the emission characteristic of the optoelectronic semiconductor chip can be approximated by a point-shaped light source, wherein the emission focal point indicates the geometrical location of this point-shaped light source. The emission focal point can in particular be suitable for defining a vertex for the first and the second emission angle.

Alternatively, the reflector can also be implemented in a non-collimating form, so that the lighting device is implemented as a divergent lighting device.

Preferably, the reflecting surface can be at least partially implemented as an elliptical paraboloid or as a rotational paraboloid. This can mean in particular that at least one of the first and second boundary lines is implemented as an ellipse or circle, and direct connecting lines between the first and second boundary lines along the reflecting surface are implemented as parts of a parabola. In particular, the receiving region of the reflector can be arranged in the vertex region of the paraboloid. Alternatively, the reflecting surface can also be implemented as part of an ellipsoid, a sphere or as a free-form surface. The first and/or the second boundary line can in this case also have, for example, a polygonal shape.

In another embodiment the reflector comprises a thermally conducting material. In particular, the reflector can be manufactured from a thermally conducting material. This has the advantage of allowing a good distribution of the heat emitted by the optoelectronic semiconductor chip over the entire reflector material, which also means that efficient dissipation of the heat to the environment is possible. The reflector here can in particular comprise a metal, for instance aluminum. Using aluminum as a reflector material can enable long-term stability of the lighting device, since aluminum does not, for example, tend to become brittle or yellow.

In particular, the reflecting surface can comprise anodized aluminum. Alternatively or additionally, the reflecting surface can also comprise another reflecting material, for example silver. In this case, the reflector can be plated or coated, for example with silver, in the area of the reflecting surface.

A reflector made of aluminum with a reflecting surface made of anodized aluminum can then advantageously have a high thermal conductivity, and a high reflectivity of the reflecting surface for the electromagnetic radiation generated by the optoelectronic semiconductor chip, together with a simple construction and uncomplicated and inexpensive manufacture.

In one embodiment, the reflecting surface has a reflectivity of greater than or equal to 85% for the electromagnetic radiation generated by the optoelectronic semiconductor chip. The reflecting surface preferably has a reflectivity of at least 90%, and particularly preferably a reflectivity greater than or equal to 99%.

### BRIEF DESCRIPTION OF THE DRAWINGS

Further advantages and advantageous embodiments and further developments are obtained from the embodiments described in the following, in combination with FIGS. 1A to 3.

They show:

FIG. 1A shows a schematic illustration of a lighting device according to one exemplary embodiment,

FIG. 1B shows the emission characteristic of an optoelectronic semiconductor chip according to one exemplary embodiment,

FIGS. 2A to 2C show schematic illustrations of reflector geometries according to further exemplary embodiments, and

FIG. 3 shows a schematic illustration of a lighting device according to a further exemplary embodiment.

In the embodiment examples and figures, equivalent components, or components that have the same effect, are designated in each case with the same reference numbers. The elements and components illustrated and their relative proportions are absolutely not to be regarded as true to scale, rather, individual elements, such as, for example, layers, assembly parts, components and regions, can be represented in exaggerated size or thickness for improved comprehension and/or illustration.

### DETAILED DESCRIPTION

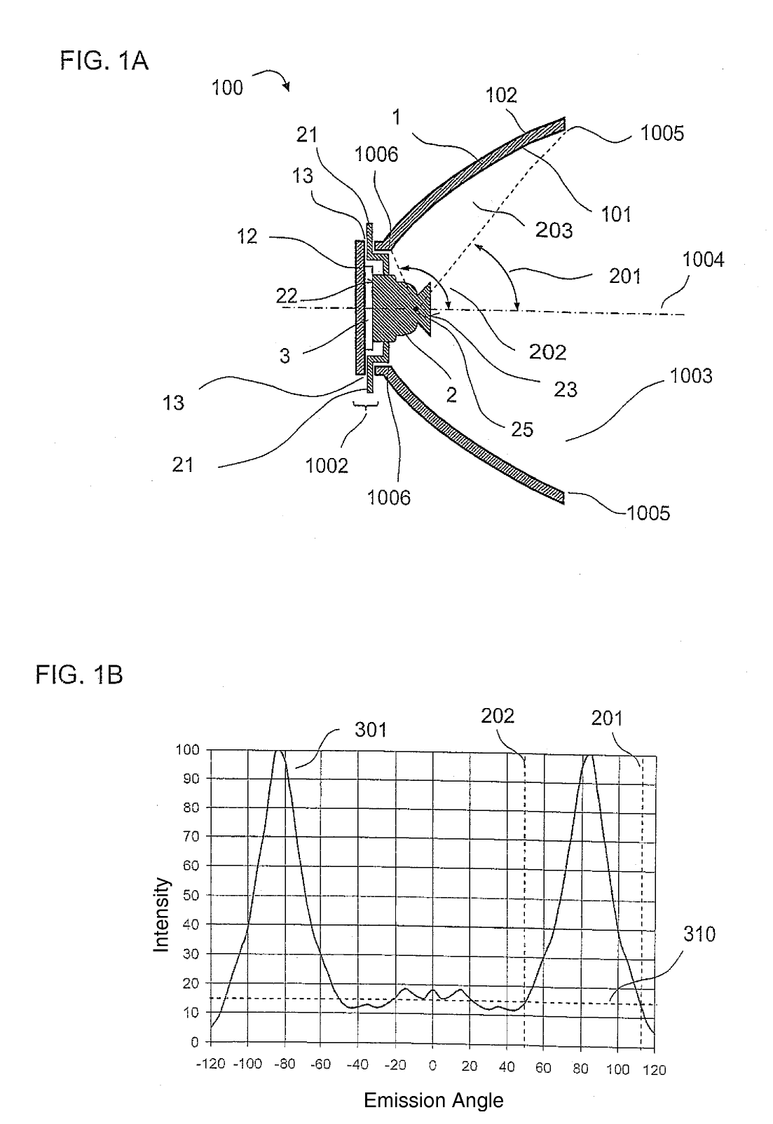

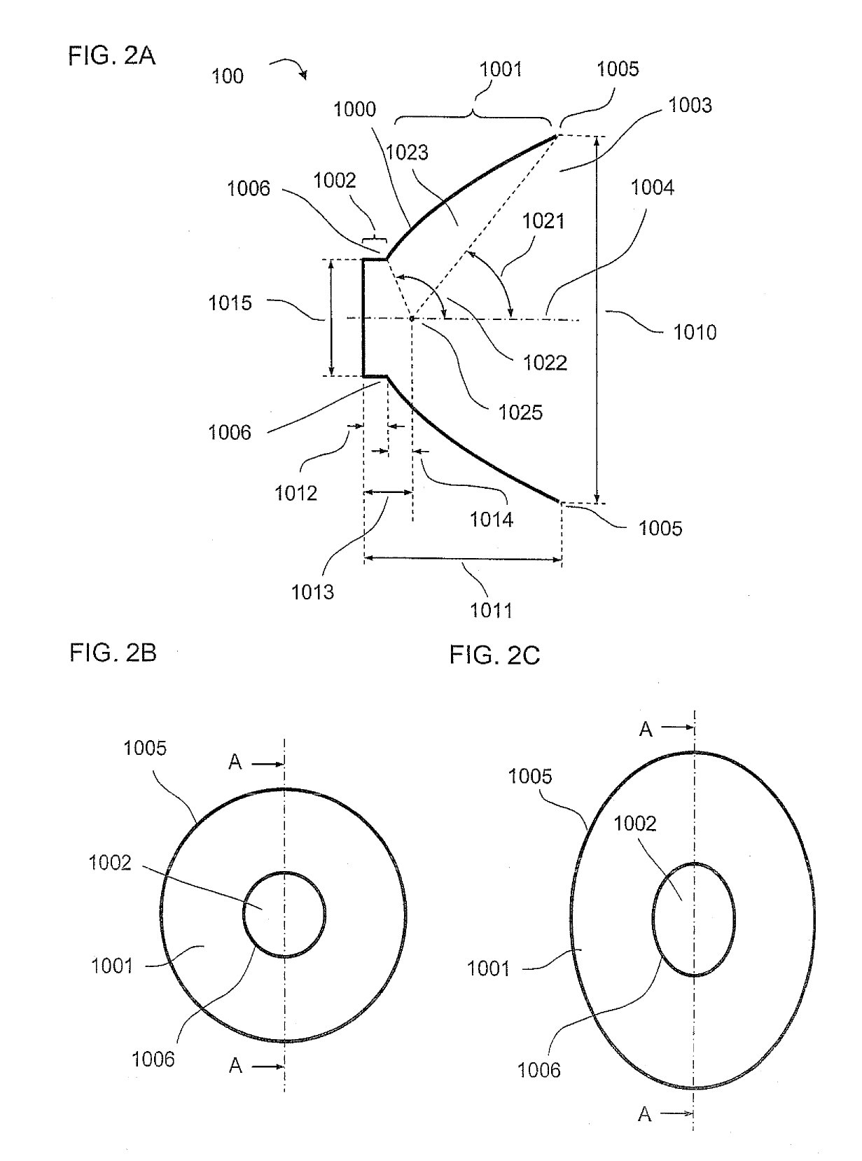

In FIG. 1A an exemplary embodiment of a lighting device 100 is shown. The lighting device 100 has a reflector 1. Exemplary embodiments for reflector geometries are described in greater detail in combination with FIGS. 2A to 2C.

The reflector 1 has a receiving region 1002, in which an optoelectronic semiconductor chip 2 is arranged. For example, the optoelectronic semiconductor chip 2 is mounted by means of screws or clamps (not shown) on a contact surface 12 in the receiving region 1002. The optoelectronic semiconductor chip 2 has electrical contacts 21, which are led through openings 13 arranged laterally in the receiving region 1002, and can be connected outside the reflector 1 to a current and/or voltage supply (not shown). The optoelectronic semiconductor chip 2 can thus be mounted in the receiving region 1002 in such a way that it can be removed again without damage to the reflector. This means that the optoelectronic semiconductor chip 2 can be for example replaced and/or disposed of separately from the reflector 1, which allows a high recycling capability of the reflector 1 separately from the disposal of the optoelectronic semiconductor chip 2.

For exact positioning of the optoelectronic semiconductor chip 2, a spacing element 3 made of a thermally conducting material, for example one or more spacer washers with a thickness of around a half to several millimeters, can be arranged between the optoelectronic semiconductor chip 2 and the contact surface 12. In particular, providing spacer washers 3 of various thicknesses can facilitate precise positioning of the optoelectronic semiconductor chip 2.

In particular, the reflector 1 comprises the contact surface 12 in the receiving region 1002, over which the optoelectronic semiconductor chip 2 is in thermal contact with the reflector 1 by means of a mounting surface 22. Heat that is generated during the operation of the optoelectronic semiconductor chip 2 can thus be conducted over the mounting surface 22 of the optoelectronic semiconductor chip 2 on to the contact surface 12 of the receiving region 1002 and therefore on to the reflector 1.

The reflector 1 comprises a thermally conducting material or is manufactured from this, in particular in the exemplary embodiment shown, from aluminum. This means that the heat generated by the optoelectronic semiconductor chip 2 can be dissipated over the entire reflector 1. In particular, the heat is emitted over the surface 101, which forms an inner side of the reflector 1, and the surface 102, which forms an outer surface of the reflector 1, to the environment, for example air. Owing to the large-area contact of the reflector 1 over the surfaces 101, 102 with the environment, the heat can be efficiently conducted away from the optoelectronic semiconductor chip 2, which means that an additional heat sink is not necessary.

In the exemplary embodiment shown, the surface 101 is constructed of anodized aluminum and therefore as a reflecting surface 101, which is bounded by the first boundary line 1005 and the second boundary line 1006. In particular, electromagnetic radiation, which is emitted by the optoelectronic semiconductor chip 2 on to the reflecting surface 101, can be deflected by the reflecting surface 101 into a room area to be lit. For this purpose, the reflector 1 comprises a light output aperture 1003, through which the electromagnetic radiation from the lighting device deflected by the reflecting surface 101 can be emitted.

In this arrangement the optoelectronic semiconductor chip 2 has a rotationally symmetric side-emitting emission characteristic. In particular, the optoelectronic semiconductor chip 2 is constructed in such a way that a majority of the emitted electromagnetic radiation is emitted into the solid angular emission region 203, which is bounded by the first emission angle 201 and the second emission angle 202. The first and second emission angles 201, 202 are in this case defined relative to an axis of symmetry 1004 of the reflector 1, as is shown in greater detail in combination with FIGS. 2A to 2C. In particular, an emission focal point 25 or a light focal point 25 respectively, can be defined for the optoelectronic semiconductor chip 2 in order to enable a simplified characterization of the emission characteristic to be made. Exemplary embodiments for rotationally symmetric side-emitting optoelectronic semiconductor chips are known to a person skilled in the art and will therefore not be discussed further at this point.

FIG. 1B shows the emission characteristic 301 of a known optoelectronic semiconductor chip 2 from the prior art.

Here the x-axis shows the emission angle in degrees relative to the axis of symmetry 1004, and the y-axis a measure of the intensity of the emitted electromagnetic radiation as a function of the emission angle. In particular, the optoelectronic semiconductor chip emits a majority of the total emitted electromagnetic radiation between the first emission angle 201 of about 50 degrees and the second emission angle 202 of about 110 degrees. The first and the second emission angle 201, 202 can be defined, for example, by a minimum emission intensity or an intensity threshold value 310. For an emission angle close to 0 degrees, which corresponds to an emission from the top 23 of the optoelectronic semiconductor chip 2, only a small portion of the electromagnetic radiation is emitted. Therefore, for an optoelectronic semiconductor chip 2 of this kind, a screen or a cap for preventing this type of emission is unnecessary.

The lighting device 100 shown in the exemplary embodiment according to FIG. 1A, owing to its simple and material-saving construction and the related low weight, can be suitable, for example, for the emission of visible, preferably white light, for mobile applications such as in flashlights or cycle headlamps. If an optoelectronic semiconductor chip 2 that emits in the infrared wavelength range is used, then use of the lighting device is conceivable for example in surveillance cameras or for instrumentation purposes. In particular, the optoelectronic semiconductor chip 2 can have a power consumption of at least approximately one Watt.

The schematic reflector geometry of a reflector according to two preferred exemplary embodiments is shown in FIGS. 2A to 2C. The following explanations relate to all of FIGS. 2A to 2C.

FIG. 2A shows the contour line 1000 of a reflector geometry along the plane section AA of FIG. 2B or 2C respectively. FIG. 2B shows a reflector geometry with a circular first boundary line 1005 and a circular second boundary line 1006, whereas FIG. 2C shows a reflector geometry with an elliptical first and second boundary line 1005 and 1006. In particular, the plane section AA in FIG. 2C extends along the primary axes of the elliptical first and second boundary lines 1005 and 1006.

In the region 1001 the contour line 1000 of the reflector has the form of part of a parabola, which means that in the region 1001 the reflector is constructed as a rotational paraboloid according to FIG. 2B or as an elliptical paraboloid according to FIG. 2C. The region 1001 represents the reflecting surface 101 according to FIG. 1. In the region 1002 the reflector is constructed in the form of a circular cylinder according to the exemplary embodiment of FIG. 2B, or as an elliptical cylinder according to the exemplary embodiment of FIG. 2C, wherein the region 1002 represents the receiving region according to FIG. 1A. In particular, the region 1001 is bounded by the first boundary line 1005 and the second boundary line 1006, wherein the contour line 1000 crosses over from region 1001 into region 1002 at the second boundary line 1006. The second boundary line 1006 in FIG. 1A additionally therefore represents a line of contact between the reflecting surface 101 and the receiving region 1002.

The first boundary line 1005 encloses a reflector aperture 1003, through which light can be emitted into a room area to be lit.

The parabolically shaped region 1001 of the reflector contour 1000 has a focal point 1025. The connecting lines between the focal point 1025 and the first boundary line 1005, or between the focal point and the second boundary line 1006, enclose the angle 1021 and the angle 1022 respectively, with an axis of symmetry 1004 through the center of the first and second boundary line 1005, 1006. The electromagnetic radiation of a light source which is arranged at the focal point 1025 and which emits electromagnetic radiation into the region 1023, which is defined by the angles 1021 and 1022, can therefore be deflected in a collimated manner through the aperture 1003 into a room area to be lit. In particular for this purpose, the emission focal point 25 of the optoelectronic semiconductor chip 2 is arranged according to FIG. 1A at the focal point 1025. The first angle 1021 has a value of at least around 30 degrees. The first angle 1021 preferably corresponds to the first emission angle 201 of the optoelectronic semiconductor chip 2 according to FIG. 1A, and the second angle 1022 corresponds to the second emission angle 202 of the optoelectronic semiconductor chip 2, in order to be able to ensure optimal usage of the reflecting surface 101 according to the exemplary embodiment of FIG. 1A.

When an optoelectronic semiconductor chip 2 is used, which has an emission characteristic according to FIG. 1B, the dimensioning of the reflector described as follows has proved to be advantageous. It should be mentioned here that the dimensions described are to be understood purely as an example and not to be limiting.

The reflector comprises an opening 1003 in connection with the first boundary line 1005, with a diameter 1010 of less than about 50 mm and particularly preferably of about 39 mm, and a diameter 1015 of the second boundary line 1006, and therefore also of the receiving region 1002, of about 13 mm. The diameter 1015 is particularly preferably greater than or equal to the size of the mounting surface 22 of the optoelectronic semiconductor chip 2. The depth 1012 of the receiving region 1002 is about 2.2 mm and the distance 1013 of the focal point 1005 from the contact region 12 of the receiving region 1002 is about 4.5 mm. The overall length 1011 of the reflector has a value of around 21 mm.

Alternatively, the depth 1012 of the receiving region can also be equal to 0 mm, for example, so that the receiving region 1002 is shaped as a flat surface of the parabolically shaped reflector contour 1000.

The optical efficiency of a lighting device according to the exemplary embodiments of FIGS. 1A to 2C can reach a theoretical value of 89%, at a reflectivity of the reflecting surface 101 of 90%. at an almost perfect reflection capacity of 99% with a silver-plated or silver coated reflecting surface 101, an optical efficiency of 97% can be possible in theory.

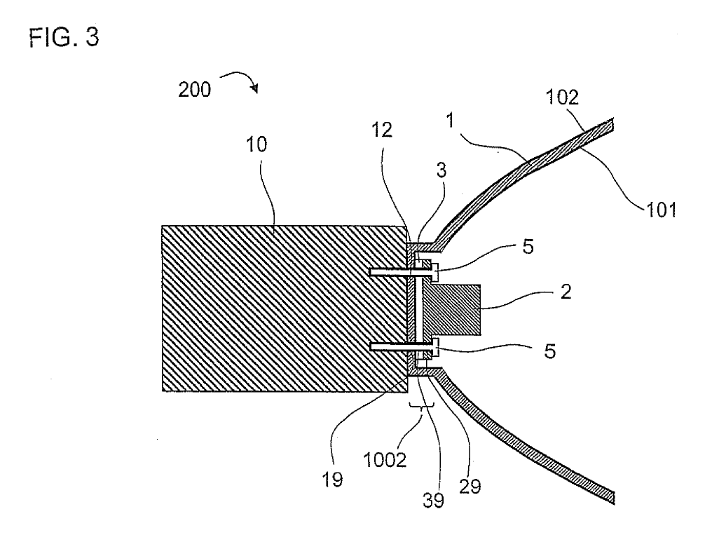

In FIG. 3 an exemplary embodiment of a lighting device 200 is shown, which additionally comprises a carrier body 10. The reflector 1 and the optoelectronic semiconductor chip 2 and a spacing element 3 can in this case be mounted on to the carrier body 10 by means of pin-shaped connecting elements 5. These pin-shaped connecting elements 5 can for example be screws, perhaps made of metal. For this purpose, the optoelectronic semiconductor chip 2, the spacing element 3 and the contact surface 12 in the receiving region 1002 of the reflector 1 have openings 29, 39, 19 with the same hole pattern, which in particular can be specified in advance by means of mounting holes in the optoelectronic semiconductor chip 2.

The invention is not limited to the embodiment examples by the fact that the description is based on them. Rather, the invention encompasses each new feature, as well as any combination of features, which includes in particular every combination of features in the patent claims, even if this feature or this combination itself is not explicitly disclosed in the patent claims or exemplary embodiments.

1. A lighting device, comprising:
an optoelectronic semiconductor chip, which emits electromagnetic radiation and generates heat in operation, and
a reflector, wherein the reflector deflects electromagnetic radiation by means of a reflecting surface, and the reflector dissipates the heat generated by the optoelectronic semiconductor chip.

2. The lighting device according to claim 1, wherein the heat dissipated by the optoelectronic semiconductor chip can be emitted to the environment by the reflector over a surface of the reflector.

3. The lighting device according to claim 1, wherein the heat generated by the optoelectronic semiconductor chip is emitted to the environment substantially exclusively by means of the reflector.

4. The lighting device according to claim 1, wherein the reflector comprises a receiving region, in which the optoelectronic semiconductor chip is mounted.

5. The lighting device according to claim 4, wherein the receiving region of the reflector is thermally coupled to the optoelectronic semiconductor chip.

6. The lighting device according to claim 4, further comprising a spacing element is arranged between the receiving region and the optoelectronic semiconductor chip.

7. The lighting device according to claim 6, wherein the spacing element comprises a thermally conducting material.

8. The lighting device according to claim 1, further comprising a carrier body, on which the reflector is mounted.

9. The lighting device according to claim 8, wherein
the reflector has openings, and
the optoelectronic semiconductor chip is mounted on the carrier body through the openings.

10. The lighting device according to claim 1, wherein the reflector has an aperture, an electrical contact for the optoelectronic semiconductor chip passing through the aperture.

11. The lighting device according to claim 1, wherein the optoelectronic semiconductor chip is mounted on the reflector by means of a plug-in connection, screw connection or clamp connection.

12. The lighting device according to claim 1, wherein the optoelectronic semiconductor chip has a rotationally symmetric side-emitting emission characteristic.

13. The lighting device according to claim 12, wherein the optoelectronic semiconductor chip emits at least 85% of the electromagnetic radiation into a solid angular emission region arranged to a side of the optoelectronic semiconductor chip with a first emission angle and a second emission angle.

14. The lighting device according to claim 13, wherein the reflecting surface of the reflector covers the solid angular emission region.

15. The lighting device according to claim 13, wherein the reflecting surface of the reflector is bounded by a first boundary line and a second boundary line, and the first and the second boundary lines cover the first and the second emission angles respectively.

16. The lighting device according to claim 1, wherein the reflector is implemented in the form of a collimator.

17. The lighting device according to claim 16, wherein the reflecting surface is shaped at least partially in the form of an elliptical paraboloid or a rotational paraboloid.

18. The lighting device according to claim 17, wherein the reflecting surface has a focal point, the optoelectronic semiconductor chip has an emission focal point, and the emission focal point is arranged at the focal point of the reflecting surface.

19. The lighting device according to claim 1, wherein the reflector comprises a thermally conductive material.

20. The lighting device according to claim 1, wherein the reflector comprises a reflecting material.

21. The lighting device according to claim 1, wherein the reflector comprises aluminum.

22. The lighting device according to claim 21, wherein the reflecting surface comprises anodized aluminum or silver.

23. The lighting device according to claim 1, wherein the reflecting surface has a reflectivity greater than or equal to 85% for the electromagnetic radiation generated by the optoelectronic semiconductor chip.

24. The lighting device according to claim 1, wherein the optoelectronic semiconductor chip is connected to the reflector by a detachable connection.
